(19) United States
(12) Patent Application Publication
(10) Pub. No.: US 2007/0082450 A1
(43) Pub. Date: Apr. 12, 2007

(54) Semiconductor device and method of manufacturing such a semiconductor device

(75) Inventors: Marcus Johannes Henricus Van Dal, Leuven (BE); Radu Catalin Surdeanu, Leuven (BE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., 5621 BA EINDHOVEN (NL)

(21) Appl. No.: 10/575,288

(22) PCT Filed: Oct. 7, 2004
(86) PCT No.: PCT/IB04/52021

§ 371 Date: Apr. 11, 2006

(30) Foreign Application Priority Data
Oct. 17, 2003 (EP) 03103857.3

(51) Int. Cl. H01L 21/336; H01L 29/788

(52) U.S. Cl. 438/301; 257/315; 438/303

(57) ABSTRACT

The invention relates to a semiconductor device (10) with a substrate and a semiconductor body (1) comprising a first FET (3) with a source (2) and a drain (3) that are provided with connection regions (2B, 3B) of a metal silicide, and that are connected to source and drain extensions (2A, 3A) bordering a channel region (4) below a gate (6) and having a smaller thickness and a lower doping concentration than the source (2) and the drain (3). The source (2) and drain (3) and the source and drain extensions (2A, 3A) are connected to each other by means of an intermediate region (2C, 3C) of the first conductivity type having a thickness and a doping concentration ranging between the thickness and doping concentration of the source (2) and drain (3) and the extensions (2A, 3A) thereof. In this way, the occurrence of leakage currents and the risk of a short circuit between the connection regions (2B, 3B) and the substrate is limited, while the advantages of the use of source and drain extensions (2A, 3A) are preserved. Preferably, the intermediate regions (2C, 3C) are positioned below spacers (7) next to the gate (6), and they are preferably formed using a, preferably tilted, ion implantation.

The invention relates to a semiconductor device with a substrate and a semiconductor body of silicon which comprises a field effect transistor having a source region which borders on the surface of the semiconductor body and which is connected to a lower-doped, thinner source region extension and having a drain region which borders on the surface of the semiconductor body and which is connected to a lower-doped, thinner drain region extension, which regions and extensions are of a first conductivity type, and having a channel region situated between said regions and extensions, which channel region is of a second conductivity type, opposite to the first conductivity type, and having a gate electrode separated from the channel region by a dielectric region, the source region and the drain region being provided with a connection region containing a metal silicide. Such a device is present particularly, and in large numbers, in so-termed (C)MOS (=(Complementary) Metal Oxide Semiconductor Field Effect Transistor) ICs (=Integrated Circuits). The invention also relates to a method of manufacturing such a device.

A device of the type mentioned in the opening paragraph is known from United States patent specification U.S. Pat. No. 5,554,549, published on 10 Sep. 1996. In said document it is argued that a connection region of a source region which contains a metal silicide may cause a short-circuit between the connection region and the substrate at the location where the metal silicide is situated above a superfluous additional extension of the source region and of the drain region, which additional extension is situated on a side of the source region and drain region facing away from the gate electrode. The presence of this additional extension is connected with a specific method of manufacturing the relevant MOS FET (=Field Effect Transistor), which also comprises a source region extension and a similar drain region extension, which border on the gate electrode. To avoid such a short-circuit it is proposed to adapt the manufacture such that said superfluous additional extension(s) are no longer formed.

A drawback of the known device resides in that it may still exhibit a high leakage current or even a short-circuit between the connection region and the substrate. The problem manifests itself, in particular, if the dimensions of the device are very small, such as in the case of a sub-100 nm generation of (C)MOS ICs.

A drawback of the known method resides in that it requires comparatively many steps, leading to a higher cost price and possibly an adverse effect on the yield.

The object of the present invention therefore is to provide a device wherein said drawback is absent or substantially absent, and wherein the leakage current is very low and short-circuits are precluded.

To achieve this, a method of the type mentioned in the opening paragraph is characterized in accordance with the invention in that the source region and the source region extension, and the drain region and the drain region extension are in each case connected with each other via an intermediate region of the first conductivity type the thickness and doping concentration of which range between those of the region and the extension which are connected with one another by the intermediate region. The invention is based first of all on the recognition that the still occurring leakage currents, or even short-circuits, in the known device develop at the point where, for example, the source region, which is often completely covered with the metal silicide, overlaps, or at least touches, the source region extension. As this region is very thin and comparatively lightly doped, a comparatively high leakage current through this region may occur or even a short-circuit with the substrate may take place. This problem manifests itself, in particular, if the dimensions of the device are small and the metal silicide is formed by reaction of a metal deposited on the semiconductor body with silicon of the semiconductor body. The invention is further based on the recognition that this problem can be solved by connecting the source region and the source region extension with an intermediate region having an intermediate thickness and doping concentration. At the location where the metal silicide borders on the intermediate region or even demonstrates an overlap with said region, the leakage current and the risk of a short-circuit is reduced because this region has a larger thickness and a higher doping concentration. By virtue thereof, on the one hand, the leakage current is limited and breakdown is precluded while, on the other hand, the advantages of the source region extension remain intact. The invention is further based on the recognition that such an intermediate region can be formed very readily, so that the manufacture of the device remains simple.

In a preferred embodiment of a device in accordance with the invention, the metal silicide is partly recessed in the semiconductor body. Such a recessed metal silicide forms notably in a manufacturing process where the metal silicide is formed by reaction of a metal deposited on the semiconductor body and the underlying silicon of the semiconductor body. It is then that the measure in accordance with the invention is particularly effective.

In a favorable embodiment, a spacer of an electrically insulating material is situated on the semiconductor body on either side of the gate electrode, and the intermediate region and the associated extension are situated below this spacer, viewed in projection. With the aid of such a spacer, both the source region (and the drain region) and the associated intermediate region can be formed, as will become clear later on in the text, while the metal silicide demonstrates no, or substantially no, overlap with the intermediate region and hence remains at a safe distance from the source region extension.

Preferably, the intermediate region is formed by means of ion implantation. This technique is very suitable because it can also advantageously be used to manufacture the source region and the source region extension.

Furthermore, this technique can suitably be used to form an intermediate region below a spacer because the angle which the implantation makes with the surface of the semiconductor body may also be oblique, so that it becomes easier to form the intermediate region through the spacer.

A method of manufacturing a semiconductor device with a substrate and a semiconductor body of silicon which comprises a field effect transistor, wherein, at the surface of the semiconductor body, a source region is formed which is connected with a lower-doped, thinner source region extension and a drain region is formed which is connected with a lower-doped, thinner drain region extension, which regions and extensions are provided with a first conductivity type, and between which a channel region of a second conductivity type, opposite to the first conductivity type, is formed which is provided with a dielectric region on which a gate electrode is formed, and wherein the source region and the drain region are provided with a connection region which comprises a metal silicide, is characterized in accordance with the invention in that an intermediate region of the first conductivity type is formed in each case between the source region and the source region extension and between the drain region and the drain region extension, which intermediate region is provided with a thickness and a doping concentration which range between those of the region and the extension which are connected to one another by the intermediate region. A device in accordance with the invention having the associated advantages is thus obtained.

In a preferred embodiment of a method in accordance with the invention, the metal silicide is formed by providing a metal on the semiconductor body and allowing this metal to react with silicon of the semiconductor body to form said metal silicide. Preferably, a spacer of an electrically insulating material is formed on either side of the gate electrode, and the intermediate region is formed by an ion implantation of a doping element of the first conductivity type, said ion implantation being carried out at an acute angle with the normal to the surface of the semiconductor body. Good results are possible using an angle of between 0 degrees and 45 degrees, preferably between 20 and 40 degrees.

A suitable implantation energy ranges between approximately 1 and 10 keV. The implantation dose ranges between, for example, 5×10¹³ at/cm² and 5×10¹⁴ at/cm², and preferably ranges from 1 to 2×10¹⁴ at/cm².

In a suitable modification, the intermediate region is formed immediately before or after the formation of the source region and the drain region, and the intermediate region and the source region, the drain region and the intermediate region are tempered during the same step. The method thus requires comparatively little adaptation and/or extension compared to known methods.

These and other aspects of the invention are apparent from and will be elucidated with reference to the embodiment(s) described hereinafter.

In the drawings:

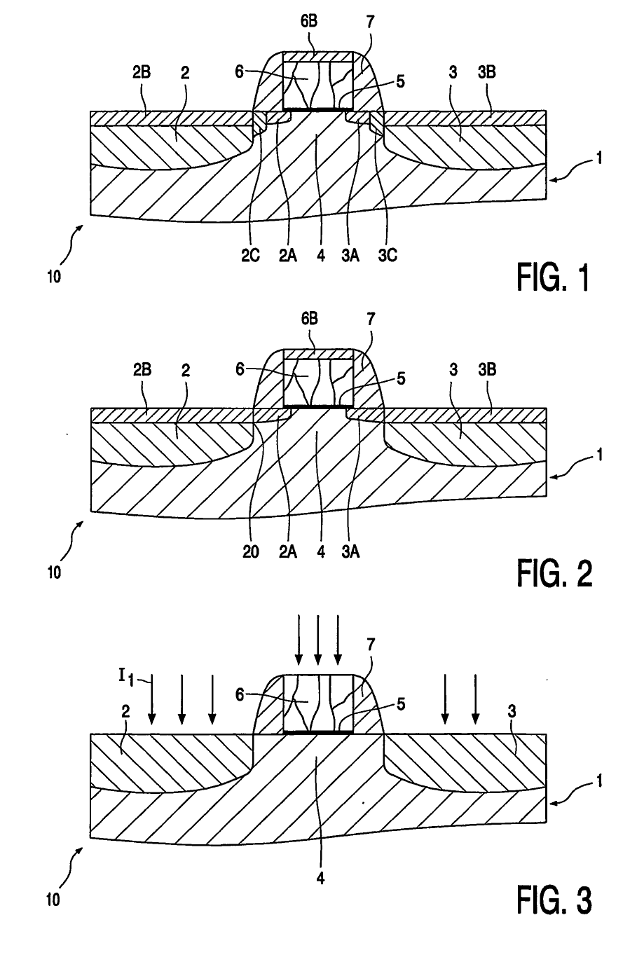

FIG. 1 is a diagrammatic, cross-sectional view at right angles to the thickness direction of a semiconductor device in accordance with the invention, FIG. 2 is a diagrammatic, cross-sectional view at right angles to the thickness direction of a known semiconductor device, and FIGS. 3 through 6 are diagrammatic, cross-sectional views at right angles to the thickness direction of a semiconductor device in successive stages of the manufacture using an embodiment of a method in accordance with the invention.

The Figures are not drawn to scale and some dimensions, such as dimensions in the thickness direction, are exaggerated for clarity. In the different Figures, corresponding regions or parts are indicated by means of the same hatching or the same reference numeral, whenever possible.

FIG. 1 is a diagrammatic, cross-sectional view at right angles to the thickness direction of a semiconductor device in accordance with the invention. FIG. 2 is a diagrammatic, cross-sectional view at right angles to the thickness direction of a known semiconductor device. Both devices 10 comprise a semiconductor body 1, which, in this case, contains a silicon semiconductor substrate, which is not separately shown in the drawing. The device 10 comprises, in practice, isolation regions (not shown) at the edges, such as a so-termed trench or LOCOS (=Local Oxidation of Silicon) isolation. In practice, the semiconductor body 1 also often comprises n-type as well as p-type regions for forming both NMOS and PMOS transistors, only one of which is shown here. At the surface of the semiconductor body 1 there is an, in this case n-type, source region 2 and a drain region 3 with an, in this case p-type, channel region 4 between them, above which there is a dielectric region 5, in this case of silicon oxynitride. Source and drain region 2, 3 are connected to a source and drain region extension 2A, 3A, respectively, which are situated below spacers 7, in this case of silicon dioxide, which border on a gate electrode 6, in this case of polycrystalline silicon. The thickness and the doping concentration of the source and drain regions 2, 3 lie in the range between, respectively, 40 and 70 nm and 10²¹ and 5×10²¹ at/cm³. For the extensions 2A, 3A of these regions 2, 3, said values are, respectively, 10 to 30 nm and 10²⁰ and 10²¹ at/cm³. The gate electrode has a width, in this case, between 10 and 100 nm and a thickness between 50 and 150 nm, while the width of the spacer 7 is, for example, in the range of 40 to 120 nm. Source and drain regions 2, 3 are covered with a connection region 2B, 3B which contains a metal silicide, in this case cobalt disilicide having a thickness in the range of 25 to 35 nm. The gate electrode 6 is covered with a connection region 6B of the same material.

In the known device 10 (see FIG. 2), an increased leakage current or even breakdown may occur between the connection regions 2B, 3B and the substrate at a point indicated by means of reference numeral 20. In the device in accordance with the invention (see FIG. 1), there is an intermediate region 2C, 3C between the source and drain regions 2, 3 and the associated extensions 2A, 3A, which intermediate region has an intermediate thickness and an intermediate doping concentration. The thickness, in this case, ranges from approximately 20 to 50 nm and the doping concentration ranges between 10¹⁸ and 5×10¹⁸ at/cm³. By virtue of these intermediate regions 2C, 3C, the leakage current at the location of the critical region 20 in the known device is limited in a device 10 in accordance with the invention, as is the risk of breakdown. By virtue thereof, the properties of the diode between the source and drain region 2, 3 and the substrate are substantially improved and hence also the properties of the MOSFET of this example.

In this example, the metal silicide region 2B, 3B is at least partly recessed in the semiconductor body 1 because it is formed by deposition of a metal on the surface of the semiconductor body 1 which is reacted with the silicon of the semiconductor body in a thermal treatment. In the drawing, the region 2B, 3B is entirely recessed. In practice, the upper face of the silicide region 2B, 3B may even be situated below the surface of the semiconductor body 1. In such a device 10, the advantage of the measure in accordance with the invention is comparatively substantial. The intermediate region 2C, 3C is preferably formed, as is the case in this example, by means of an ion implantation and is situated substantially entirely below the spacer 7. The inventive device 10 of this example is manufactured in the following manner using a method in accordance with the invention.

FIGS. 3 through 6 are diagrammatic, cross-sectional views at right angles to the thickness direction of a semiconductor device in successive stages of the manufacture using an embodiment of a method in accordance with the invention. The initial steps (see FIG. 3) are partly customary and not separately shown in this case. The surface of the semiconductor body 1 is covered with a dielectric layer 5, which, in this case, comprises silicon oxynitride and has a thickness in the range between 0.5 and 1.5 nm. An, in this case, 50 nm thick polycrystalline silicon layer 6, which may or may not be doped, is provided thereon by means of, in this case, CVD (=Chemical Vapor Deposition). Next, the gate electrode 6 is defined by means of photolithography and etching. The spacers 7 are formed by uniformly depositing a dielectric layer, which is subsequently anisotropically etched. Next, the source and drain regions 2, 3 are formed by means of a first ion implantation I₂. In this process, the gate electrode 6 is not shielded, so that also the silicon of the gate electrode is doped.

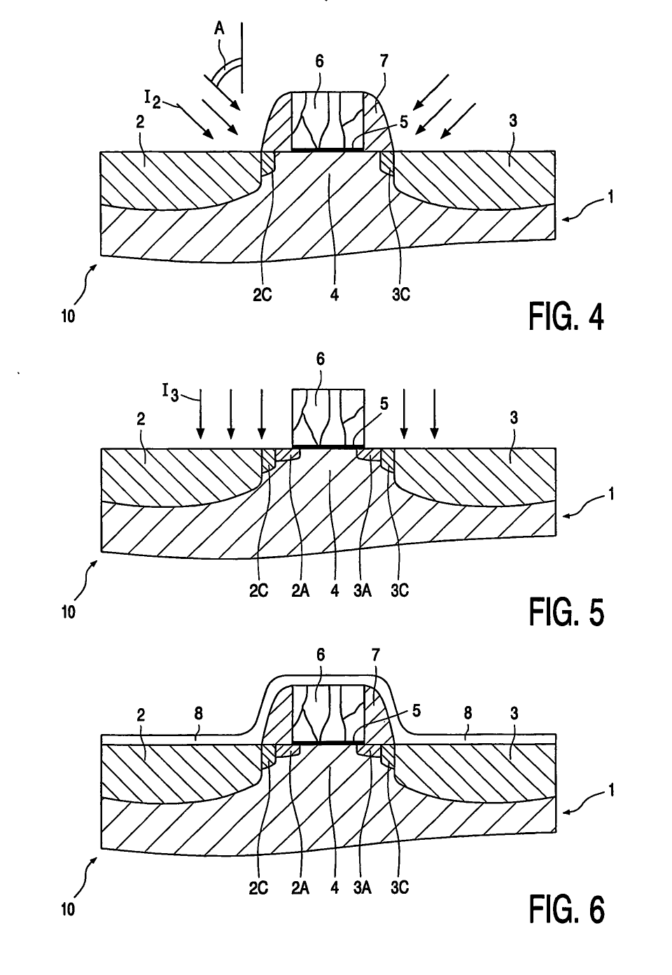

Subsequently (see FIG. 4), the intermediate regions 2C, 3C are formed by means of a second ion implantation I₂. This implantation I₂ is carried out at an angle A in the range between 0 and 45 degrees with respect to the normal, in this case approximately 20 degrees with respect to the normal. As a result, the intermediate region 2C, 3C is formed below the spacer 7. Next, both implantations I₁ and I₂ are tempered by a thermal treatment using RTA (=Rapid Thermal Annealing) at a temperature in the range of 900 to 1100 degrees Celsius.

Subsequently (see FIG. 5), the spacers 7 are removed by means of etching, after which the source and drain region extensions 2A, 3A are formed by means of a third ion implantation I₃. This implantation I₃ is then tempered by a thermal treatment, such as a so-termed flash or laser RTA (=Rapid Thermal Anneal).

Subsequently (see FIG. 6), a metal layer 8, in this case of cobalt, is provided by vapor deposition. A reaction product, i.e. a metal-rich metal silicide, is thus formed in a first low-temperature thermal treatment, at the location of the source and drain regions 2, 3 and the gate electrode 6, from which the mask has meanwhile been removed. The redundant metal on said regions and the entire metal layer 8 at the location of the spacers 7 is then removed by means of etching. In a further thermal treatment at a higher temperature the cobalt-rich silicide is then converted to cobalt disilicide, resulting (see FIG. 1) in the formation of the connection regions 2B, 3B of the source and drain regions 2, 3 and of the connection region 6B of the gate electrode 6.

Finally, the manufacture of the transistor T is completed in a customary manner. That is to say, one or more dielectric layers are applied and provided with contact openings, after which a conductive layer, for example of aluminum, is applied and patterned, and connection conductors for the source and drain regions 2, 3 and the gate electrode 6 are formed from said conductive layer. For the sake of simplicity, these steps are not shown in the Figures. Individual devices 10 are obtained by means of a separation technique, such as sawing.

The invention is not limited to the example of embodiment described herein, and, within the scope of the invention, many variations and modifications are possible to those skilled in the art. For example, devices having a different geometry and/or different dimensions may be manufactured. Instead of a substrate of Si, use may be made of a substrate of glass, ceramic or a synthetic resin. The semiconductor body may then be formed by the so-termed SOI (=Silicon On Insulator). For this purpose use may or may not be made of a so-termed substrate transfer technique.

It is further noted that materials other than those mentioned in the examples may be used within the scope of the invention. For example, instead of cobalt use may be made of other metals such as nickel or titanium. Instead of a gate electrode containing silicon, use may advantageously be made of a metal gate electrode. It is also possible to use different deposition techniques for said, or other, materials, such as epitaxy, CVD, sputtering and vapor deposition. Instead of wet-chemical etching methods, “dry” techniques may be used, such as plasma etching, and conversely. It is further noted that the device may comprise other active and passive semiconductor elements or electronic components, whether or not in the form of an IC.

1. A semiconductor device (10) with a substrate and a semiconductor body (1) of silicon which comprises a field effect transistor having a source region (2) which borders on the surface of the semiconductor body (1) and which is connected to a lower-doped, thinner source region extension (2A) and having a drain region (3) which borders on the surface of the semiconductor body (1) and which is connected to a lower-doped, thinner drain region extension (3A), which regions (2, 3) and extensions (2A, 3A) are of a first conductivity type, and having a channel region (4) situated between said regions and extensions, which channel region is of a second conductivity type, opposite to the first conductivity type, and having a gate electrode (6) separated from the channel region (4) by a dielectric region (5), the source region (2) and the drain region (3) being provided with a connection region (2B, 3B) containing a metal silicide, characterized in that the source region (2) and the source region extension (2A), and the drain region (3) and the drain region extension (3A) are in each case connected with each other via an intermediate region (2C, 3C) of the first conductivity type the thickness and doping concentration of which range between those of the region (2, 3) and the extension (2A, 3A) which are connected with one another by the intermediate region (2C, 3C).

2. A semiconductor device (10) as claimed in claim 1, characterized in that the connection region (2B, 3B) is recessed in the semiconductor body (1).

3. A semiconductor device (10) as claimed in claim 1, characterized in that a spacer (7) of an electrically insulating material is situated on the semiconductor body (1) on either side of the gate electrode (6), and the intermediate region (2C, 3C) and the associated extension (2A, 3A) are situated below these spacers (7), viewed in projection.

4. A semiconductor device as claimed in claim 1, characterized in that the intermediate region (2C, 3C) is formed by means of ion implantation.

5. A method of manufacturing a semiconductor device (10) with a substrate and a semiconductor body (1) of silicon which comprises a field effect transistor, wherein, at the surface of the semiconductor body (1), a source region (2) is formed which is connected with a lower-doped, thinner source region extension (2A) and a drain region (3) is formed which is connected with a lower-doped, thinner drain region extension (3A), which regions (2, 3) and extensions (2A, 3A) are provided with a first conductivity type, and between which a channel region (4) of a second conductivity type, opposite to the first conductivity type, is formed which is provided with a dielectric region (5) on which a gate electrode (6) is formed, and wherein the source region (2) and the drain region (3) are provided with a connection region (2B, 3B) which comprises a metal silicide, characterized in that an intermediate region (2C, 3C) of the first conductivity type is formed in each case between the source region (2) and the source region extension (2A) and between the drain region (3) and the drain region extension (3A), which intermediate region is provided with a thickness and a doping concentration which range between those of the region (2, 3) and the extension (2C, 3C) which are connected to one another by the intermediate region (2C, 3C).

6. A method as claimed in claim 5, characterized in that the metal silicide is formed by providing a metal (8) on the semiconductor body (1) and allowing this metal to react with silicon of the semiconductor body (1) to form the metal silicide of the connection region (2B, 3B).

7. A method as claimed in claim 5, characterized in that a spacer (7) of an electrically insulating material is formed on either side of the gate electrode (6), and the intermediate region (2C, 3C) is formed by an ion implantation (I₂) of a doping element of the first conductivity type, the ion implantation (I₂) being carried out at an acute angle (A) with the normal to the surface of the semiconductor body (1).

8. A method as claimed in claim 7, characterized in that for the angle (40) at which the ion implantation (I₂) is carried out an angle (A) between 0 degrees and 45 degrees is chosen, and preferably an angle (A) between 20 and 40 degrees.

9. A method as claimed in claim 7, characterized in that the ion implantation (I₂) is carried out at an energy between 0.5 and 10 keV, and a flux between 5×10¹³ at/cm² and 5×10¹⁴ at/cm².

10. A method as claimed in claim 7, characterized in that the source region (2) and the drain region (3) are also formed by means of an ion implantation (I₁), and the intermediate region (2C, 3C) is formed immediately before or after the formation of the source region (2) and the drain region (3), and all these regions (2, 2C, 3, 3C) are tempered in the same heat treatment.
